(19) United States
(12) Patent Application Publication
(10) Pub. No.: US 2009/0250791 A1
(43) Pub. Date: Oct. 8, 2009

(54) Crystalline Semiconductor Stripes

(76) Inventors: Themistokles Afentakis, Vancouver, WA (US); Robert S. Sposili, Vancouver, WA (US); Apostolos T. Voutsas, Portland, OR (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(21) Appl. No.: 12/099,744

(22) Filed: Apr. 8, 2008

(51) Int. Cl. H01L 21/20; H01L 27/12

(52) U.S. Cl. 257/618; 438/479; 257/E21.09; 257/E27.112

(57) ABSTRACT

Crystalline semiconductor stripes and an associated fabrication process are provided. The method provides an insulator substrate, and deposits a semiconductor layer overlying the insulator substrate. The semiconductor layer is irradiated using a scanning step-and-repeat laser annealing process, which agglomerates portions of the semiconductor layer. In response to cooling agglomerated semiconductor material, oriented crystalline semiconductor stripes are formed on the insulator substrate. The crystalline semiconductor stripes are aligned approximately with a straight line stripe axis overlying a top surface of the insulating substrate. Each crystalline semiconductor stripe includes a plurality of consecutive ring segments aligned with the stripe axis. The rings segments have a width about equal to the laser annealing process step distance. The crystalline semiconductor stripes typically have a top surface shape of a truncated cylinder or a parabolic cross section.

### RELATED APPLICATIONS

This application is related to a pending application entitled, CRYSTALLINE SEMICONDUCTOR STRIPE TRANSISTOR, invented by Afentakis et al., Ser. No. ______, filed ______, Attorney Docket No. SLA2344, which is incorporated herein by reference.

### BACKGROUND OF THE INVENTION

1. Field of the Invention

This invention generally relates to integrated circuit (IC) fabrication and, more particularly, to crystalline semiconductor material stripes and an associated fabrication process.

2. Description of the Related Art

The benefits of low-defect-density active silicon films are well known for use in thin film transistors (TFTs). High crystallinity silicon has a higher mobility and steeper subthreshold slope, while device uniformity and reliability also improves. Thin-film transistors are usually employed in display applications, where, among other processing constraints, there is a need for a reduced thermal budget due to the properties of the glass substrate. These two requirements, i.e., low defect density and low thermal budget, have made laser crystallization the prominent approach for fabricating high performance thin film transistors from polycrystalline or amorphous Si active films.

The conventional laser annealing processes for Si crystallization/recrystallization are not without problems, however. The resulting polycrystalline structure has a typically higher surface roughness than the initial, as-deposited film, and areas of high defect density exist between grains (grain boundaries). Therefore, the TFT effective mobility can suffer from surface scattering and interface/bulk trapping effects. The device uniformity and most importantly, mobility deviation around the mean, can be much higher than in either amorphous Si or single-crystal Si transistors.

Crystal structure and device property uniformity are addressed by a number of variations of the laser crystallization process, falling into two basic categories: a) laser beam and scanning strategy engineering (beam profile shaping, sequential scanning & overlapping techniques, etc.); and, b) active film structure engineering (antireflective coat deposition and patterning, etc.)

In this group of optimization variables, laser energy and beam profile are crucial in order to obtain the best crystal structure, i.e., repeatable large grains. Extreme laser energies, either too high or too low are undesirable because they lead to very fine grains (the result of copious film nucleation) or agglomeration (which breaks film continuity). For a static, flood-irradiation scheme, the energy window associated with the largest grains is very narrow and strongly correlated with film thickness. Since inevitable process variations can cause large variations in film quality, if energy is confined to this narrow range, a sub-optimal range or overlapping scanning techniques (such as sequential lateral solidification) are employed for increased robustness.

FIGS. 1A through 1C are perspective views depicting steps in a conventional laser annealing process (prior art). The process typically begins with a glass or quartz substrate, onto which one or several insulating basecoat layers are deposited (FIG. 1A). Amorphous or polycrystalline Si is then deposited, commonly with a chemical vapor deposition (CVD) process (FIG. 1B). After laser crystallization, the film retains its mean thickness, but typically the surface roughness has increased. However, the crystal structure of the film has improved significantly over the as-deposited film (FIG. 1C).

It would be advantageous if semiconductor crystalline structures could be formed for use in TFTs with a decreased surface roughness, as compared to the product of conventional laser annealing processes.

### SUMMARY OF THE INVENTION

The present invention uses a laser beam and scanning strategy engineering technique to form crystallized semiconductor stripes oriented in a controlled shape. The crystallized semiconductor stripes can be used in the fabrication of a thin-film transistor structure whose active region is Si agglomerated through laser annealing. In contrast to conventional laser annealing processes, the claimed invention can be used to form tapered agglomerated Si island sidewalls, resulting in more uniform gate insulator and gate electrode coverage, and minimizing high electric field points that are usually present around the corners. Further, the surface roughness of the agglomerated islands is lower, resulting in a lower defect density.

Accordingly, a method is provided for fabricating oriented crystalline semiconductor stripes. The method provides an insulator substrate, and deposits a semiconductor layer overlying the insulator substrate. The semiconductor layer is irradiated using a scanning step-and-repeat laser annealing process, which agglomerates portions of the semiconductor layer. In response to cooling agglomerated semiconductor material, oriented crystalline semiconductor stripes are formed on the insulator substrate.

The crystalline semiconductor stripes are aligned approximately with a straight line stripe axis overlying a top surface of the insulating substrate. Each crystalline semiconductor stripe includes a plurality of consecutive ring segments circumscribing the stripe axis. The ring segments have a width about equal to the laser annealing process step distance. The crystalline semiconductor stripes typically have a top surface shape approximating a truncated cylinder or a parabolic cross section, such top surface shapes alternatively being described herein as selected from a group consisting of a truncated cylinder or a parabolic cross-section. In some aspects, a surface feature is formed in the top surface of the insulator substrate, and crystalline semiconductor stripes are oriented in an axis that is in alignment with the surface feature.

Additional details of the above-described method and an oriented crystalline semiconductor stripe structure are provided below.

### BRIEF DESCRIPTION OF THE DRAWINGS

FIGS. 1A through 1C are perspective views depicting steps in a conventional laser annealing process (prior art).

FIG. 2A is a plan view and FIGS. 2B and 2C are partial cross-sectional views of an oriented crystalline semiconductor stripe structure.

FIGS. 3A through 3C are partial cross-sectional views depicting a first variation of the crystalline semiconductor stripe of FIGS. 2A-2C.

FIGS. 4A and 4B are plan and partial cross-sectional views, respectively, depicting a second variation of the crystalline semiconductor stripe of FIGS. 2A-2C.

FIGS. 5A through 5C depict steps in the present invention laser annealing process.

FIGS. 6A and 6B are partial cross-sectional views depicting steps in the formation of a crystalline semiconductor stripe formed as a result of a trench surface feature in the substrate.

FIGS. 7A through 7E are plan (top) views depicting steps in a TFT fabrication process.

FIG. 8A through 8C depict examples of crystalline Si stripes formed from a 100 nm-thick layer of Si film over a quartz substrate using different energy densities.

FIG. 9 is a flowchart illustrating a method for fabricating oriented crystalline semiconductor stripes.

### DETAILED DESCRIPTION

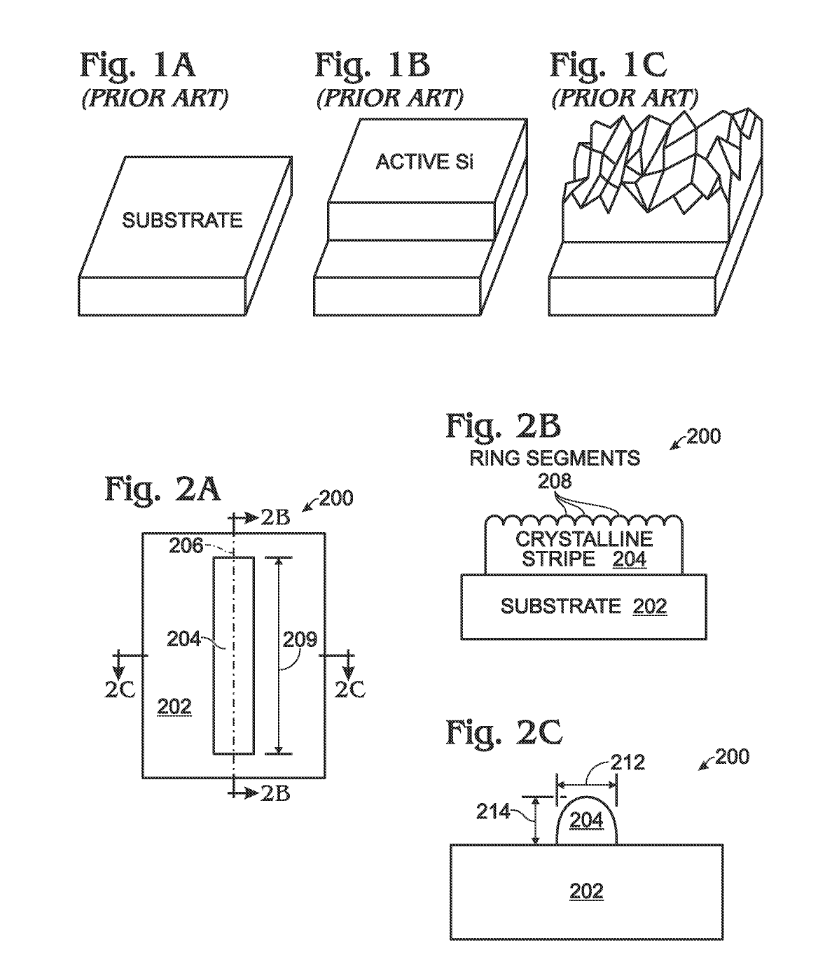

FIG. 2A is a plan view and FIGS. 2B and 2C are partial cross-sectional views of an oriented crystalline semiconductor stripe structure. The crystalline semiconductor stripes are referred to as “oriented” in that the stripes are generally aligned in a controlled manner with the direction of laser scan used in fabrication. The crystalline semiconductor stripe structure 200 comprises an insulator substrate 202. A crystallized semiconductor material has a stripe shape 204 that is aligned with an axis 206 (as seen from above in the plan view) overlying the insulator substrate 202. In one aspect as shown, the axis 206 is a straight line (as shown in FIG. 2A). The crystallized stripe 204 has a plurality of sequential ring segments 208 circumscribing the axis 206.

In one particular aspect, starting with an initial silicon film thickness of 50 nanometers and irradiating with laser energies in the range of 600 and 640 milli-Joules per square centimeter (mJ/cm²), the crystallized stripe 204 has a length 209 in the range of about 10 millimeters to 10 centimeters, a width 212 of about 2.4 micrometers, and a height 214 of about 260 nanometers. In one aspect, the crystalline semiconductor stripe 204 has a top surface shape 210 approximating a truncated cylinder (FIG. 2C) or a parabolic cross section (not shown).

The insulator substrate 202 material may be an oxide, nitride, or ceramic. In one aspect, the insulator substrate 202 material is either an oxide or a nitride, and includes a first material. In this aspect, the crystalline semiconductor stripe 204 also includes the first material. For example, the crystalline semiconductor stripe 204 may be Si and the insulator substrate 202 may be silicon oxide. More generally, the crystalline semiconductor stripe 204 may be Si, Ge, or SiGe. Typically, the crystalline semiconductor stripe has either a single-crystal or polycrystalline structure.

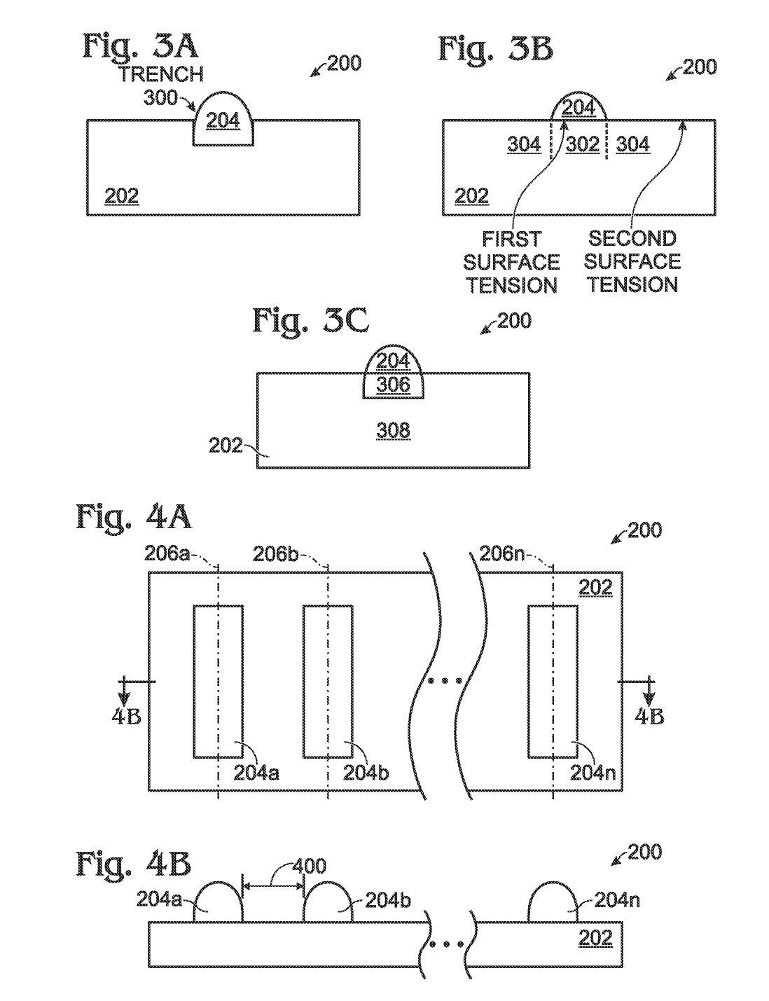

FIGS. 3A through 3C are partial cross-sectional views depicting a first variation of the crystalline semiconductor stripe of FIGS. 2A-2C. In this aspect the insulator substrate 202 has a surface feature, and the crystalline semiconductor stripe axis 206 is aligned with the surface feature. In FIG. 3A the surface feature is a trench 300. In FIG. 3B the surface feature is a region with a first surface tension 302 formed in an insulator substrate 202 having an overall second surface tension 304. In FIG. 3C the surface feature is a region of a first insulator material 306 formed in an insulator substrate 202 made from an overall second material 308. In one aspect not shown, the surface feature may have a curved shape (as seen from above) and the stripe follows the surface feature, even if the surface feature direction varies from the direction of laser scanning.

FIGS. 4A and 4B are plan and partial cross-sectional views, respectively, depicting a second variation of the crystalline semiconductor stripe of FIGS. 2A-2C. This aspect comprises a plurality of crystalline stripes 204a through 204n, where n is not limited to any particular value. The crystalline stripes are oriented with a corresponding plurality of parallel axes 206a through 206n, with a pitch 400 between stripes that depends primarily on the initial semiconductor film thickness and the substrate material. In one particular aspect, for a 50 nanometer-thick silicon film on a silicon dioxide substrate, the pitch 400 between stripes is about 11 micrometers.

### FUNCTIONAL DESCRIPTION

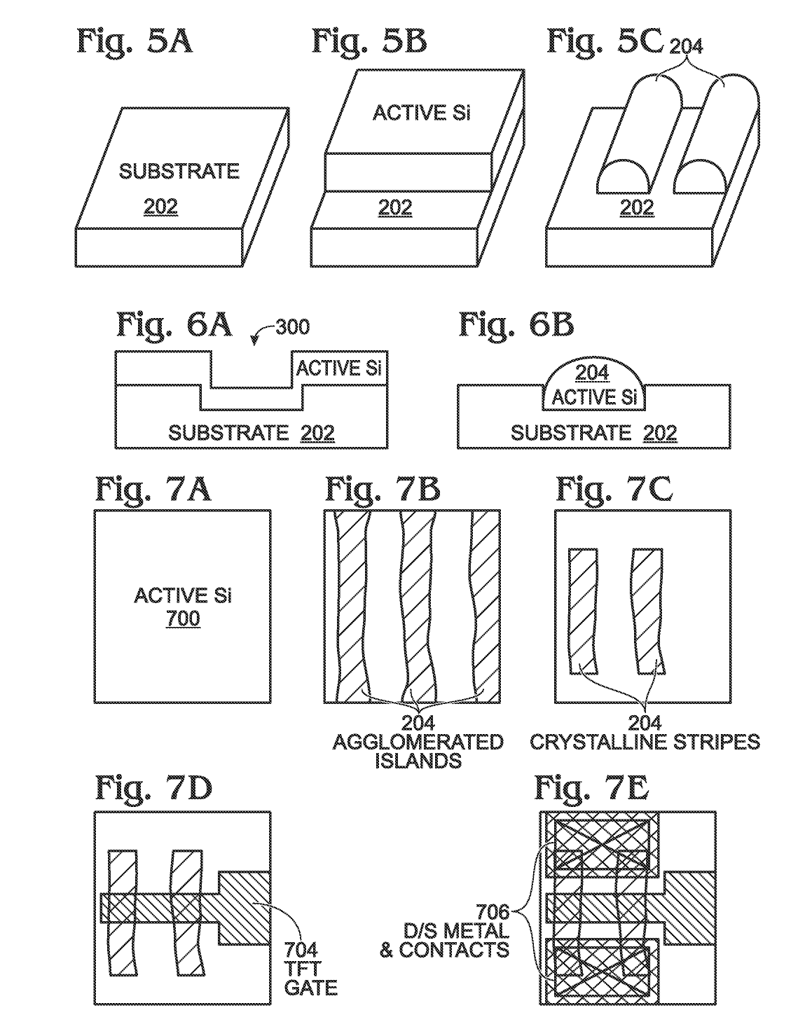

FIGS. 5A through 5C depict steps in the present invention laser annealing process. In contrast to the process depicting in FIGS. 1A-1C, the process typically begins with a glass or quartz substrate, onto which one or several insulating basecoat layers are deposited (FIG. 5A). Amorphous or polycrystalline Si is then deposited, commonly with a CVD process (FIG. 5B). The film is laser-irradiated at or beyond the agglomeration limit. At this point, the entire irradiated area of Si melts. In the case of molten silicon on a silicon dioxide or silicon nitride substrate, the surface energy difference between the semiconductor film and the substrate favors agglomeration, which is defined as the complete retraction of the molten film from some portions of the substrate and mass-transport towards the formation of a typically discontinuous surface structure. This is a direct result of the molten film assuming a structure that minimizes its surface tension. Thus, the active Si de-wets from the surface, forming the approximately semi-cylindrical structures shown in FIG. 5C. These structures are formed roughly in parallel with the laser scanning direction.

FIGS. 6A and 6B are partial cross-sectional views depicting steps in the formation of a crystalline semiconductor stripe formed as a result a trench surface feature in the substrate. The substrate is patterned before the deposition of active Si. The Si active film follows the substrate topography prior to crystallization (FIG. 6A). After agglomeration the film may de-wet and be confined to the trench area. In other embodiments, other topographies may be formed in the substrate or the top of the Si film can be patterned prior to annealing, in order to induce the film to agglomerate in preferred locations. In some aspects, portions of the crystalline semiconductor stripes may be removed after annealing. If semiconductor material remains in undesired areas of the substrate after annealing, it can removed during this active layer patterning step without interference with the crystalline stripe sidewalls.

FIGS. 7A through 7E are plan (top) views depicting steps in a TFT fabrication process. As an example, the present invention process may be used to selectively agglomerate Si films for the active area of polycrystalline Si TFTs. Assuming a top-gate TFT fabrication process, the active silicon is deposited using a conventional process, such as CVD, onto a patterned (FIGS. 3A-3C) or non-patterned (FIGS. 2A-2C) substrate. Once the crystalline stripes are formed in the proper regions, the top-gate, self-aligned TFT fabrication sequence proceeds in accordance with conventional Si-based processes.

In FIG. 7A the active Si layer 700 is deposited. In FIG. 7B the active Si is agglomerated with laser irradiation forming agglomerated islands or crystalline Si stripes 204. The crystalline Si stripes are patterned in FIG. 7C. FIG. 7D depicts gate insulator and gate electrode 704 deposition and patterning. In FIG. 7E metal contacts 706 are formed to TFT drain/source (D/S) regions. In one aspect (not shown), trenches are etched into the substrate prior to the step depicted by FIG. 7A, in order to aid the formation of the Si structures shown in FIG. 7B.

Some variables that are known to influence the crystalline semiconductor stripe structure include: laser energy density, active Si thickness, between-pulse translation steps, and substrate properties such as thermal conductance, hydrophilic, and hydrophobic properties.

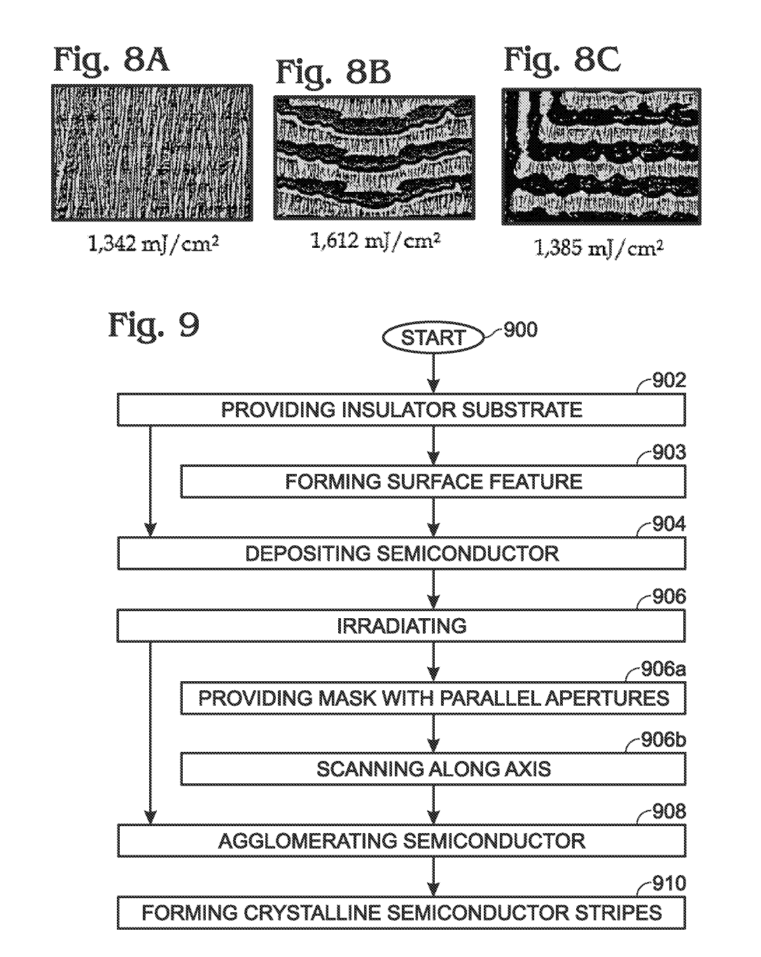

FIG. 8A through 8C depict examples of crystalline Si stripes formed from a 100 nm-thick layer of Si film over a quartz substrate using different energy densities. The structure of FIG. 8C is desirable in that the crystalline stripes are formed in parallel straight-line axes. The thicknesses of the crystalline stripes are typically substantially different from that of the as-deposited film. The resultant stripes have a structure that is responsive to the as-deposited film thickness and the surface energy of the underlying substrate.

FIG. 9 is a flowchart illustrating a method for fabricating oriented crystalline semiconductor stripes. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 900.

Step 902 provides an insulator substrate. For example, the insulator substrate can be an oxide, nitride, or ceramic. Step 904 deposits a semiconductor layer overlying the insulator substrate. Typically, the semiconductor is Si, Ge, or SiGe. Step 906 irradiates the semiconductor layer using a scanning step-and-repeat laser annealing process. Step 908 agglomerates portions of the semiconductor layer. In response to cooling agglomerated semiconductor material, Step 910 forms oriented crystalline semiconductor stripes on the insulator substrate. The crystalline semiconductor stripes formed in Step 910 have a shape responsive to the scanning rate, step distance, pulse duration, and energy density of the laser annealing process (Step 906).

In one aspect, forming oriented crystalline semiconductor stripes on the insulator substrate in Step 910 includes forming oriented crystalline semiconductor stripes having a length in the range of about 10 millimeters to 10 centimeters. In another aspect, Step 910 forms crystalline semiconductor stripes aligned approximately with a straight line stripe axis overlying a top surface of the insulating substrate. In a different aspect, Step 910 forms each crystalline semiconductor stripe with a plurality of consecutive ring segments circumscribing the stripe axis. Typically, the ring segments have a width about equal to the laser annealing process step distance. The step distance is the amount traveled by the laser annealing mask (or substrate) in each “step” of the step-and-repeat laser annealing process. In another aspect, Step 910 forms crystalline semiconductor stripes having a top surface shape approximating either a truncated cylinder or a parabolic cross-section. The crystalline semiconductor stripes typically have either a single-crystal or polycrystalline structure.

In one aspect, Step 903 forms a surface feature in a top surface of the insulator substrate. The surface feature may be a trench, a region with a first surface tension formed in an insulator substrate having an overall second surface tension, or a region of a first insulator material formed in an insulator substrate made from an overall second material. Then, forming oriented crystalline semiconductor stripes on the insulator substrate in Step 910 includes forming crystalline semiconductor stripes oriented with an axis aligned with the surface feature.

In another aspect, irradiating the semiconductor layer using the scanning step-and-repeat laser annealing process in Step 906 includes substeps. Step 906a provides a mask with a plurality of parallel apertures. Step 906b scans along a first axis overlying a top surface of the insulator substrate. Then, forming oriented crystalline semiconductor stripes on the insulator substrate in Step 910 includes forming crystalline semiconductor stripes oriented in parallel to the first axis.

In one aspect, providing the insulator substrate in Step 902 includes providing either an oxide or nitride substrate that further includes a first material. Then, depositing the semiconductor layer in Step 904 includes depositing a semiconductor including the first material.

For example, depositing the semiconductor layer overlying the insulator substrate in Step 904 may include depositing a 50 nanometer Si precursor film overlying a Si dioxide substrate. Then, forming oriented crystalline semiconductor stripes in Step 910 includes forming crystalline Si stripes having a width of about 2.4 micrometers, a pitch between stripes of about 11 micrometers, and a height of about 260 nanometers.

Crystalline semiconductor stripes and an associated fabrication process have been provided. Details of particular structures, materials, and processes have been given to illustrate the invention. However, the invention is not limited to merely these examples. Other variations and embodiments of the invention will occur to those skilled in the art.

We claim:

1. A method for fabricating oriented crystalline semiconductor stripes, the method comprising:
providing an insulator substrate;
depositing a semiconductor layer overlying the insulator substrate;
irradiating the semiconductor layer using a scanning step-and-repeat laser annealing process;
agglomerating portions of the semiconductor layer; and,
in response to cooling agglomerated semiconductor material, forming oriented crystalline semiconductor stripes on the insulator substrate.

2. The method of claim 1 wherein forming oriented crystalline semiconductor stripes on the insulator substrate includes forming oriented crystalline semiconductor stripes having a length in a range of about 10 millimeters to 10 centimeters.

3. The method of claim 1 wherein forming oriented crystalline semiconductor stripes on the insulator substrate includes forming crystalline semiconductor stripes aligned approximately with a straight line stripe axis overlying a top surface of the insulating substrate.

4. The method of claim 1 wherein forming oriented crystalline semiconductor stripes on the insulator substrate includes forming each crystalline semiconductor stripe with a plurality of consecutive ring segments circumscribing the stripe axis.

5. The method of claim 4 wherein forming the plurality of consecutive ring segments includes forming rings segments have a width about equal to the laser annealing process step distance.

6. The method of claim 4 wherein forming oriented crystalline semiconductor stripes on the insulator substrate includes forming crystalline semiconductor stripes having a shape responsive to the scanning rate, step distance, pulse duration, and energy density of the laser annealing process.

7. The method of claim 1 wherein forming oriented crystalline semiconductor stripes on the insulator substrate includes forming crystalline semiconductor stripes having a top surface shape selected from a group consisting of a truncated cylinder and a parabolic cross-section.

8. The method of claim 1 further comprising:
forming a surface feature in a top surface of the insulator substrate; and,
wherein forming oriented crystalline semiconductor stripes on the insulator substrate includes forming crystalline semiconductor stripes oriented with an axis aligned with the surface feature.

9. The method of claim 8 wherein forming the surface feature in the top surface of the insulator substrate includes forming a surface feature selected from a group consisting of a trench, a region with a first surface tension formed in an insulator substrate having an overall second surface tension, and a region of a first insulator material formed in an insulator substrate made from an overall second material.

10. The method of claim 1 wherein forming oriented crystalline semiconductor stripes on the insulator substrate includes forming crystalline semiconductor stripes having a crystalline structure selected from a group consisting of single-crystal and polycrystalline.

11. The method of claim 1 wherein irradiating the semiconductor layer using the scanning step-and-repeat laser annealing process includes:
providing a mask with a plurality of parallel apertures;
and,
scanning along a first axis overlying a top surface of the insulator substrate; and,
wherein forming oriented crystalline semiconductor stripes on the insulator substrate includes forming crystalline semiconductor stripes oriented in parallel to the first axis.

12. The method of claim 1 wherein depositing the semiconductor material includes depositing a semiconductor material selected from a group consisting of Si, Ge, and SiGe.

13. The method of claim 1 wherein providing the insulator substrate includes providing a substrate selected from a group consisting of oxides, nitrides, and ceramics.

14. The method of claim 1 wherein providing the insulator substrate includes providing a substrate selected from a group consisting of an oxide and a nitride, and including a first material; and,
wherein depositing the semiconductor layer includes depositing a semiconductor including the first material.

15. The method of claim 1 wherein depositing the semiconductor layer overlying the insulator substrate includes depositing a 50 nanometer Si precursor film overlying a Si dioxide substrate; and,
wherein forming oriented crystalline semiconductor stripes includes forming crystalline Si stripes having a width of about 2.4 micrometers, a pitch between stripes of about 11 micrometers, and a height of about 260 nanometers.

16-27. (canceled)
